(19) United States
(12) Patent Application Publication
(10) Pub. No.: US 2026/0069026 A1
(43) Pub. Date: Mar. 12, 2026

(54) SUBSTRATE CLEANING BRUSH AND SUBSTRATE PROCESSING APPARATUS INCLUDING THE SAME

(71) Applicant: SAMSUNG ELECTRONICS CO., LTD., Suwon-si (KR)

(72) Inventors: Seonmin YUN, Suwon-si (KR); SEUNGMAHN LEE, Suwon-si (KR); CHOONGOANG KIM, Suwon-si (KR)

(73) Assignee: SAMSUNG ELECTRONICS CO., LTD., Suwon-si (KR)

(21) Appl. No.: 19/171,833

(22) Filed: Apr. 7, 2025

(30) Foreign Application Priority Data
Sep. 10, 2024 (KR) 10-2024-0123501

(51) Int. Cl. A46B 9/02; A46B 13/00; A46B 13/02; B24B 37/34; H01L 21/67

(52) U.S. Cl. CPC A46B 9/026; A46B 13/001; A46B 13/02; B24B 37/34; H10P 72/0412; A46B 2200/3073

(57) ABSTRACT

Provided is a substrate cleaning brush and a substrate cleaning apparatus including same. The substrate cleaning brush includes: a core portion having a cylindrical shape; a brush on the core portion, the brush including a center region and edge regions, wherein the edge regions are on opposite side of the center region; and a plurality of protruding portions on the brush, wherein a protrusion ratio of the plurality of protruding portions increases linearly from the center region to the edge regions, and wherein a width of a bottom level of at least one of the plurality of protruding portions is larger than a width of a top level of the at least one of the plurality of protruding portions.

### CROSS-REFERENCE TO RELATED APPLICATION

This U.S. non-provisional patent application is based on and claims priority to Korean Patent Application No. 10-2024-0123501, filed on Sep. 10, 2024, in the Korean Intellectual Property Office, the entire contents of which are hereby incorporated by reference.

### BACKGROUND

### 1. Field

The present disclosure relates to a substrate cleaning brush and a substrate processing apparatus including the same, and in particular, a substrate cleaning brush configured to uniformly clean a substrate and a substrate processing apparatus including the same.

### 2. Description of Related Art

A semiconductor device may be fabricated through several unit processes. For example, the processes of fabricating the semiconductor device may include a photolithography process, an etching process, and a deposition process, which are performed on a substrate. It is necessary to planarize the surface of the substrate before each process. To do this, a polishing process is performed on the substrate. After the polishing process, the surface of the substrate is cleaned by physical and chemical methods.

### SUMMARY

Provided is a substrate cleaning brush configured to uniformly clean a substrate and a substrate processing apparatus including the same.

Further provided is a substrate cleaning brush with improved durability and a substrate processing apparatus including the same.

According to an aspect of the disclosure, a substrate cleaning brush includes: a core portion having a cylindrical shape; a brush on the core portion, the brush including a center region and edge regions, wherein the edge regions are on opposite side of the center region; and a plurality of protruding portions on the brush, wherein a protrusion ratio of the plurality of protruding portions increases linearly from the center region to the edge regions, and wherein a width of a bottom level of at least one of the plurality of protruding portions is larger than a width of a top level of the at least one of the plurality of protruding portions.

According to an aspect of the disclosure, a substrate cleaning brush includes: a core portion having a cylindrical shape; a brush on the core portion, the brush including a center region and edge regions, wherein the edge regions are on opposite sides of the center region; and a plurality of protruding portions on the brush, wherein at least a portion of the plurality of protruding portions are on the brush in a spiral configuration, and wherein a width of a bottom level of at least one of the plurality of protruding portions is larger than a width of a top level of the at least one of the plurality of protruding portions.

According to an aspect of the disclosure, a substrate processing apparatus includes: a polisher configured to polish a surface of a substrate using a polishing pad; and a cleaner configured to clean and dry the substrate, wherein the cleaner includes: a brush including a center region and edge regions; and a plurality of protruding portions protruding from the brush, and wherein a protrusion ratio of the plurality of protruding portions increases linearly from the center region to the edge regions.

### BRIEF DESCRIPTION OF DRAWINGS

The above and other aspects and features of certain embodiments of the present disclosure will be more apparent from the following description taken in conjunction with the accompanying drawings, in which:

FIG. 1 is a perspective view illustrating a substrate processing apparatus according to one or more embodiments of the present disclosure;

FIGS. 2 and 3 are conceptual diagrams illustrating a brush portion of a substrate processing apparatus according to one or more embodiments of the present disclosure;

FIG. 4 is a plan view illustrating a substrate cleaning brush according to one or more embodiments of the present disclosure;

FIG. 5 is a cross-sectional view illustrating a substrate cleaning brush according to one or more embodiments of the present disclosure, taken along a line A-A′ of FIG. 4;

FIG. 6 is a cross-sectional view illustrating a portion “X” of FIG. 5;

FIG. 7 is a cross-sectional view illustrating a substrate cleaning brush according to one or more embodiments of the present disclosure, taken along a line B-B′ of FIG. 4;

FIG. 8 is an enlarged cross-sectional view illustrating a portion “Y” of FIG. 7;

FIG. 9 is a graph illustrating a protrusion ratio of a substrate cleaning brush, according to one or more embodiments of the present disclosure;

FIG. 10 is a graph illustrating a cleaning ability of a substrate cleaning brush according to one or more embodiments of the present disclosure; and

FIGS. 11 and 12 are plan views illustrating a substrate cleaning brush according to one or more embodiments of the present disclosure.

### DETAILED DESCRIPTION

Example embodiments of the disclosure will now be described more fully with reference to the accompanying drawings, in which example embodiments are shown. Like reference numerals in the drawings denote like elements, and thus their description will be omitted.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

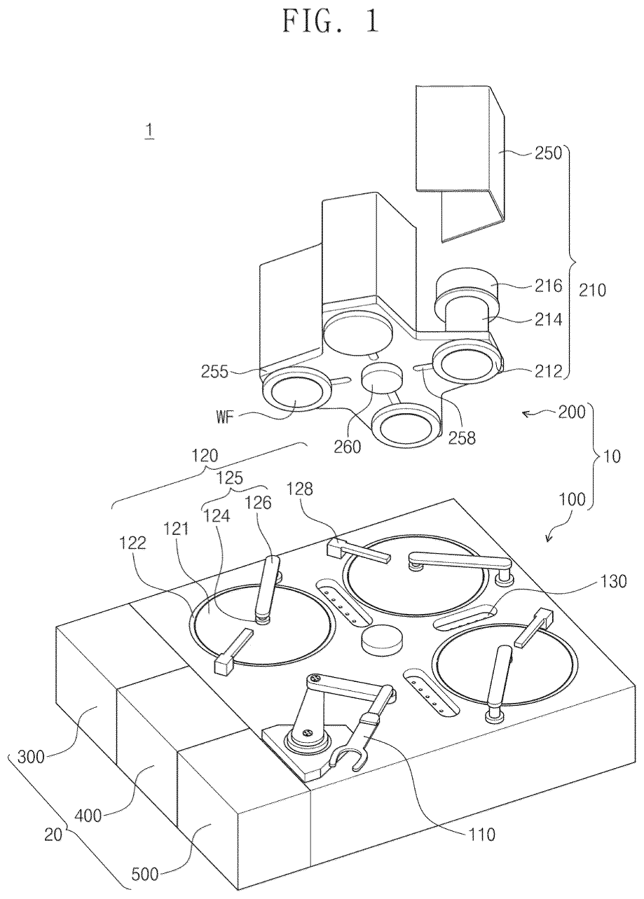

FIG. 1 is a perspective view illustrating a substrate processing apparatus according to one or more embodiments of the present disclosure.

Referring to FIG. 1, a substrate processing apparatus 1 is provided. In one or more embodiments, the substrate processing apparatus 1 may be configured to polish a surface of a substrate WF by a chemical mechanical polishing (CMP) method and to clean the polished surface of the substrate WF. For example, semiconductor patterns may be formed on the surface of the substrate WF. In the present disclosure, the term “substrate WF” may mean a silicon wafer, but the disclosure is not limited to this example. For example, the substrate processing apparatus 1 may include a polisher 10, which is configured to polish the surface of the substrate WF, and a cleaner 20, which is configured to clean the polished surface of the substrate WF.

The polisher 10 may include a lower machine 100 and a carousel 200. The lower machine 100 may include a transferring station 110, polishing stations 120, and washing stations 130.

The transferring station 110 of the polisher 10 may be used to transfer the substrate WF. The transferring station 110 may be placed on substantially the same plane as three polishing stations 120. The transferring station 110 may be configured to transfer the substrate WF, which is polished by one of the polishing stations 120, to another one of the polishing stations 120. In addition, the transferring station 110 may be configured to transfer the polished substrate WF to the cleaner 20.

Each of the polishing stations 120 may include a polishing pad 121, a platen 122, a pad conditioner 125, and a slurry supplying device 128. The polishing pad 121 may be placed on and supported by the platen 122. The platen 122 may include a driving unit. The driving unit may include a motor and may be configured to rotate the platen 122. The polishing pad 121 may be rotated together with the platen 122. Each of the polishing pad 121 and the platen 122 may have the shape of a circular plate. A top surface of the polishing pad 121 may be in contact with the substrate WF and may be used to polish a surface of the substrate WF. For example, diameters of the polishing pad 121 and the platen 122 may be about twice as large as a diameter of the substrate WF.

The pad conditioner 125 may include a conditioner head 124 and a rotating arm 126. The conditioner head 124 and the rotating arm 126 may be configured in such a way that their rotations are independently controlled. The rotating arm 126 may be configured to support the conditioner head 124 and may be used to place the conditioner head 124 on the polishing pad 121. For example, the rotating arm 126 may move the conditioner head 124 in a horizontal direction, on the polishing pad 121. The pad conditioner 125 may be used to polish a surface of the polishing pad 121. The state of the polishing pad 121 may be changed by the pad conditioner 125. For example, the pad conditioner 125 may be used to keep the polishing pad 121 in a desired state, and thus, the substrate WF may be uniformly polished.

The slurry supplying device 128 may be placed on the polishing pad 121. The slurry supplying device 128 may supply a slurry on the polishing pad 121. For example, the slurry may include a reactant (e.g., deionized water for oxidation polishing), polishing particles (e.g., silicon dioxide for oxidation polishing), and a chemical reaction catalyzer (e.g., potassium hydroxide for oxidation polishing). The slurry may be supplied to cover the top surface of the polishing pad 121. The slurry supplying device 128 may include a plurality of spraying nozzles, which are provided on a bottom surface thereof, but the disclosure is not limited to this example.

Each of the washing stations 130 may be placed between adjacent ones of the polishing stations 120. The washing stations 130 may be configured to wash the substrate WF when the substrate WF is moved to a region between the polishing stations 120.

The carousel 200 may include a polishing head systems 210 and a center pillar 260. The carousel 200 may be disposed on the lower machine 100. The polishing head systems 210 may be supported by the center pillar 260 and may be rotated about the center pillar 260 in a clockwise or counter-clockwise direction. In one or more embodiments, four polishing head systems 210 may be provided, but the disclosure is not limited to this example.

Each of the polishing head systems 210 may support the substrate WF. For example, three of the polishing head systems 210 may be configured to support and fasten the substrate WF and to press against the polishing pad 121. Thus, the surface of the substrate WF may be polished. One of the polishing head systems 210 may be configured to support and fasten the substrate WF and to move the substrate WF to a region on the transferring station 110.

Each of the polishing head systems 210 may include a polishing head 212, a spindle 214, a motor 216, and a housing 250. The polishing head 212 may be independently rotated about its own rotation axis. The polishing head 212 may be moved within openings 258, which are formed in a supporting plate 255 of the housing 250, in a horizontal direction. For example, the polishing head 212 may have the shape of a circular pillar.

The spindle 214 may be placed between the motor 216 and the polishing head 212. The spindle 214 may connect the motor 216 to the polishing head 212. The motor 216 may rotate the polishing head 212 through the spindle 214.

The housing 250 may cover the spindle 214 and the motor 216 in such a way that the spindle 214 and the motor 216 are not exposed to the outside. The supporting plate 255 of the housing 250 may be configured to expose the polishing head 212 to the outside. The supporting plate 255 of the housing 250 may be provided to have four openings 258, which are radially extended and are spaced apart from each other by an angle of about 90°.

The cleaner 20 may include a mega-sonic cleaner 300, a brush portion 400, and a drying portion 500. The cleaner 20 may be configured to remove contaminants, which are present on the surface of the substrate WF polished by the polisher 10. For example, the cleaner 20 may be configured to prevent scratching of a surface of the substrate WF.

The mega-sonic cleaner 300 may be configured to clean the substrate WF using a mega-sonic phenomenon. For example, in the mega-sonic cleaner 300, a rod vibrating at a mega-sonic frequency may be used to clean the substrate WF or the deionized (DI) water may be sprayed at a mega-sonic frequency to clean the substrate WF. In the present disclosure, the mega-sonic phenomenon may refer to a phenomenon with a frequency that is higher (e.g., about 200 kHz to about 1000 kHz) by approximately 10 to 50 times compared to that of ultrasonic waves. In one or more embodiments, the mega-sonic cleaner 300 may be omitted.

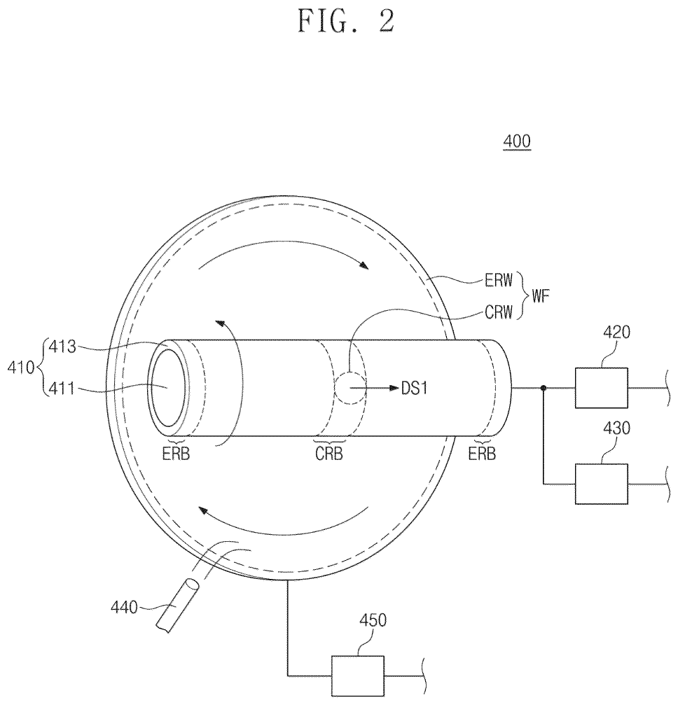

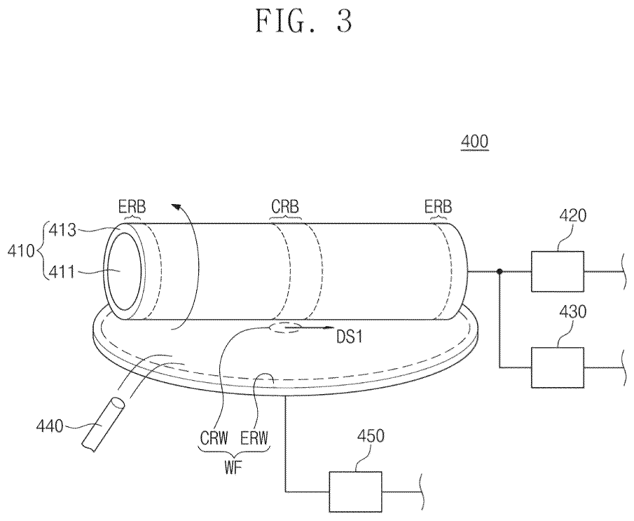

The brush portion 400 may include a substrate cleaning brush and may be configured to clean the surface of the substrate WF using the substrate cleaning brush. In the brush portion 400, the substrate WF may be cleaned using a cleaning solution and/or DI water. The brush portion 400 may be configured to rotate the substrate WF and the substrate cleaning brush at the same time. The brush portion 400 will be described in more detail with reference to FIGS. 2 and 3.

The drying portion 500 may be configured to dry the substrate WF, which is cleaned by the mega-sonic cleaner 300 and/or the brush portion 400. For example, the drying portion 500 may be used to remove the cleaning solution that is left on the surface of the substrate WF. In one or more embodiments, a drying portion 600 may be one of a spin dryer, an isopropyl alcohol (IPA) vapor dryer, and a Marangoni dryer. The spin dryer may be configured to dry the substrate WF using a centrifugal force. The IPA vapor dryer may be configured to dry the substrate WF using IPA vapor, which is produced when dry isopropyl alcohol (IPA), one of organic solvents, is heated. The Marangoni dryer may be configured to dry the substrate WF using a difference in surface tension between the deionized water and the isopropyl alcohol (IPA) formed thereon.

FIGS. 2 and 3 are conceptual diagrams illustrating a brush portion of a substrate processing apparatus according to one or more embodiments of the present disclosure.

Referring to FIGS. 2 and 3, the brush portion 400 may include a substrate cleaning brush 410, a brush driver 420, a DI water supply 430, a cleaning solution supply 440, and a substrate driver 450. The substrate WF may be provided in the brush portion 400. The substrate WF may include a center portion CRW and an edge portion ERW, which is placed around the center portion CRW. In the case where the substrate WF has the shape of a circular plate, the center portion CRW of the substrate WF may have the shape of a circle, and the edge portion ERW of the substrate WF may have the shape of a concentric circle. The edge portion ERW of the substrate WF may be spaced apart from the center portion CRW of the substrate WF in a direction DS1 along a first distance. For example, the center portion CRW may be a region of the substrate WF adjacent to a center axis of the substrate WF, and the edge portion ERW may be a region of the substrate WF adjacent to an outer side surface of the substrate WF.

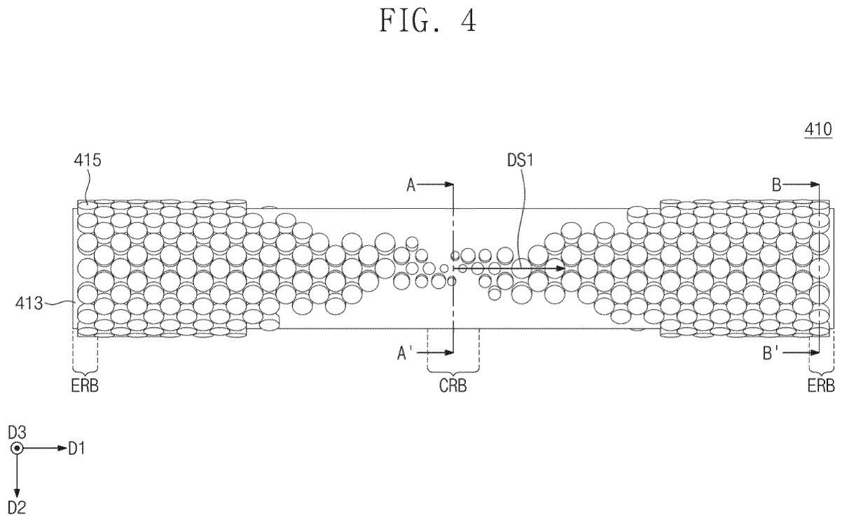

The substrate cleaning brush 410 may include a core portion 411 having a cylindrical shape and a brush 413 enclosing the core portion 411. The brush 413 of the substrate cleaning brush 410 may include a center region CRB and edge regions ERB, which are provided at both sides of the center region CRB. For example, the center region CRB may be a region of the brush 413 overlapped with the center portion CRW of the substrate WF, and the edge regions ERB may be a region of the brush 413 overlapped with the edge portion ERW of the substrate WF. The substrate cleaning brush 410 will be described in more detail with reference to FIGS. 4 to 8.

In one or more embodiments, the brush portion 400 may include two substrate cleaning brushes 410. In this case, the two substrate cleaning brushes 410 may be disposed to be symmetric with each other about the substrate WF.

The brush driver 420 may be connected to the substrate cleaning brush 410. More specifically, the brush driver 420 may be connected to the core portion 411 of the substrate cleaning brush 410 and may be used to rotate the substrate cleaning brush 410. During the rotation of the substrate cleaning brush 410, a portion of the brush 413 is in contact with the substrate WF and a surface of the substrate WF may be cleaned. In the case where two substrate cleaning brushes 410 are provided, the substrate cleaning brushes 410 may be rotated in different directions.

The DI water supply 430 may be connected to the substrate cleaning brush 410. More specifically, the DI water supply 430 may be connected to the core portion 411 of the substrate cleaning brush 410 and may be used to supply the DI water to the brush 413 through the core portion 411. The brush 413 may have a porous structure. Accordingly, the DI water may be supplied into the brush 413, and this may make it possible to prevent the brush 413 from being contaminated. In one or more embodiments, the core portion 411 may have a plurality of ejection holes, which are formed on its surface and are used to supply the DI water to the brush.

The cleaning solution supply 440 may be configured to supply a cleaning solution to a region on the substrate WF. The cleaning solution may react chemically with contaminants, which may be present on the surface of the substrate WF. Accordingly, the substrate cleaning brush 410 may be used to remove the contaminants. For example, the cleaning solution may contain at least one of ammonia (NH₄OH) and hydrofluoric acid (HF), but the disclosure is not limited to this example.

The substrate driver 450 may be connected to the substrate WF and may be used to rotate the substrate WF. For example, the substrate WF and the substrate cleaning brush 410 may be rotated at the same time. In this case, a relative velocity of the substrate WF relative to the substrate cleaning brush 410 may be increased. The rotation axis of the substrate WF may be orthogonal to the rotation axis of the substrate cleaning brush 410. Accordingly, the center portion CRW of the substrate WF may be excessively cleaned, compared with the edge portion ERW of the substrate WF. Thus, the cleaning ability of the substrate cleaning brush 410 on the substrate WF may not be uniform.

The substrate WF may be oriented in various directions with respect to the brush portion 400. In one or more embodiments, the substrate WF may be placed on a plane that is defined by a first direction D1 and a second direction D2. That is, the substrate WF may be placed horizontally with respect to the brush portion 400. In another embodiment, the substrate WF may be placed on a plane that is defined by the first direction D1 and a third direction D3. That is, the substrate WF may be placed vertically with respect to the brush portion 400.

In the present specification, the first and second directions D1 and D2 may not be parallel to each other. The third direction D3 may not be parallel to the first and second directions D1 and D2. For example, the first direction D1, the second direction D2, and the third direction D3 may be orthogonal to each other. The first and second directions D1 and D2 may be referred to as horizontal directions. The third direction D3 may be referred to as a vertical direction.

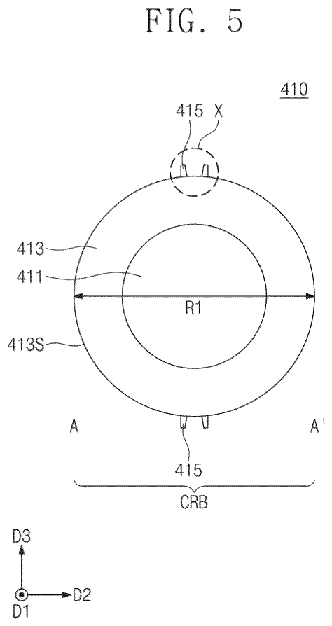

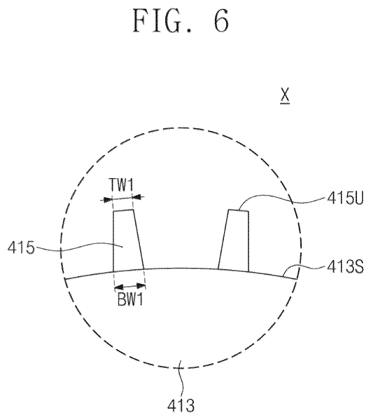

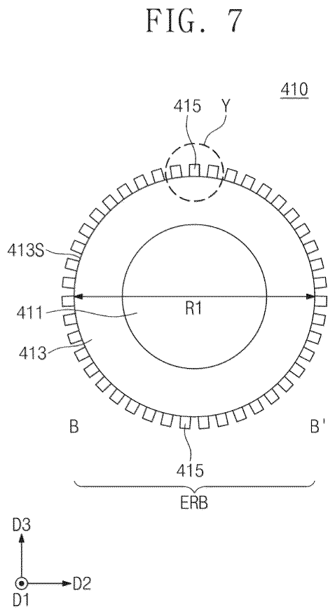

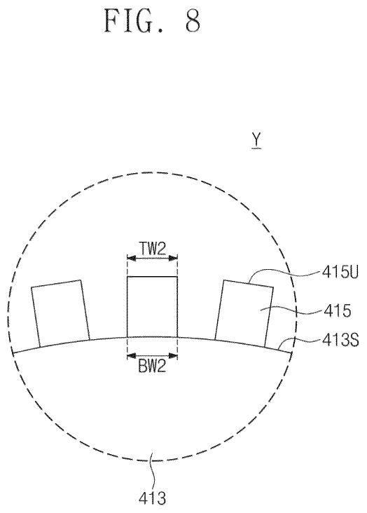

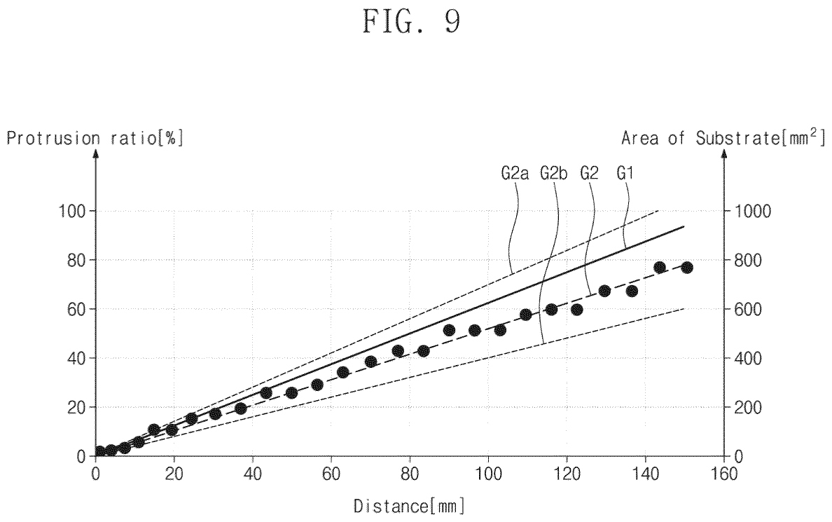

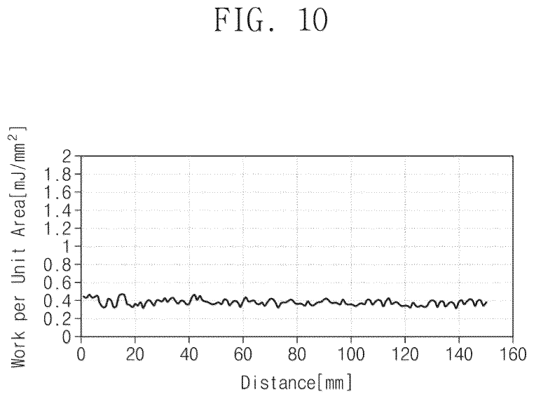

FIG. 4 is a plan view illustrating a substrate cleaning brush according to one or more embodiments of the present disclosure. FIG. 5 is a sectional view illustrating a substrate cleaning brush according to one or more embodiments of the present disclosure, taken along a line A-A′ of FIG. 4. FIG. 6 is a sectional view illustrating a portion ‘X’ of FIG. 5. FIG. 7 is a sectional view illustrating a substrate cleaning brush according to one or more embodiments of the present disclosure, taken along a line B-B′ of FIG. 4. FIG. 8 is an enlarged sectional view illustrating a portion ‘Y’ of FIG. 7. FIG. 9 is a graph illustrating a protrusion ratio of a substrate cleaning brush, according to one or more embodiments of the present disclosure. FIG. 10 is a graph illustrating a cleaning ability of a substrate cleaning brush according to one or more embodiments of the present disclosure.

Referring to FIG. 4, the brush 413 of the substrate cleaning brush 410 may have a shape extending in the first direction D1. The brush 413 may include the center region CRB and the edge regions ERB, which are placed at both sides of the center region CRB. One of the edge regions ERB may be spaced apart from the center region CRB in the direction DS1 along the first distance. Another one of the edge regions ERB may be spaced apart from the center region CRB in the direction DS1 along the first distance. In other words, the center region CRB may be placed between the two edge regions ERB, and the edge regions ERB may be placed to be symmetric with each other about the center region CRB. In one or more embodiments, the brush 413 may include at least one of poly vinyl alcohol (PVA), polyacrylic amide, urea-formaldehyde resins, melamine resins, and carboxymethyl cellulose (CMC).

The substrate cleaning brush 410 may include a plurality of protruding portions 415. The protruding portions 415 may be placed on the brush 413. The protruding portions 415 may be disposed to be symmetric with each other about the center region CRB of the brush 413, but the disclosure is not limited to this example. The protruding portions 415 may be in contact with the brush 413. For example, the protruding portions 415 may have a shape protruding from the brush 413. When viewed in a plan view, each of the protruding portions 415 may have a circular shape. The protruding portions 415 may include substantially the same material as the brush 413, and in one or more embodiments, the protruding portions 415 may be formed integrally with the brush 413. However, the disclosure is not limited to these examples.

That is, the protruding portions 415 may be placed between the center region CRB, the edge regions ERB, and the center and edge regions CRB and ERB of the brush 413. The protruding portions 415 may be spaced apart from each other to expose a portion of the brush 413. The sizes or the number of the protruding portions 415 may be different from each other in the center region CRB and the edge regions ERB. For example, the size of each of the protruding portions 415 may increase from the center region CRB to the edge regions ERB. In addition, the number of the protruding portions 415 may increase from the center region CRB to the edge regions ERB. For example, the size and the number of the protruding portions 415 may be larger in the edge regions ERB than in the center region CRB.

Referring to FIGS. 5 and 6, the brush 413 may have a circular cross-section having a first diameter R1. For example, an outer side surface 413S of the brush 413 may be a circumference of a circle that has the first diameter R1. The protruding portions 415 may be placed on the outer side surface 413S of the brush 413. The protruding portions 415 may be in contact with the outer side surface 413S of the brush 413. Each of the protruding portions 415 may have a shape protruding from the outer side surface 413S of the brush 413. In one or more embodiments, the protruding portions 415 may include substantially the same material as the brush 413, and they may form a single object. In this case, there may be no visible interface between the protruding portions 415 and the brush 413.

Each of the protruding portions 415 may have a first top width TW1 at its top level. Each of the protruding portions 415 may have a first bottom width BW1 at its bottom level. The first top width TW1 may be smaller than the first bottom width BW1. For example, the protruding portions 415 may have a cone shape. In one or more embodiments, the first top width TW1 may range from about 3 mm to about 6 mm. The first bottom width BW1 may range from about 6 mm to about 9 mm. In addition, the protruding portions 415 may have top surfaces 415U. Since each of the protruding portions 415 has a larger width at its bottom level than at its top level, it may not break as easily. Thus, the durability of the brush 413 may be improved.

As described with reference to FIGS. 2 and 3, the top surfaces 415U of the protruding portions 415 may be in contact with the substrate WF, when a cleaning process is performed on the substrate WF. During the cleaning process on the substrate WF, the outer side surface 413S of the brush 413 may be spaced apart from the substrate WF. In the present specification, an effective cleaning area in the cleaning process on the substrate WF may be given as a sum of areas of the top surfaces 415U of the protruding portions 415.

The protruding portions 415 may have a specific protrusion ratio in the center region CRB. In the present specification, the protrusion ratio may be defined as a ratio between a sectional length of the top surfaces 415U of the protruding portions 415 and a sectional length of the outer side surface 413S of the brush 413. For example, the protrusion ratio may be a value that is obtained by dividing the sectional length of the top surfaces 415U of the protruding portions 415 by the sectional length of the outer side surface 413S of the brush 413. The sectional length of the outer side surface 413S of the brush 413 may be given as the product of the first diameter R1 and pi (π), and the sectional length of the top surfaces 415U of the protruding portions 415 may be given as a sum of the first top widths TW1.

In one or more embodiments, the protrusion ratio may be less than about 5% in the center region CRB. If the protrusion ratio in the center region CRB is greater than about 5%, the substrate WF may be excessively cleaned. Accordingly, the semiconductor patterns integrated on the surface of the substrate WF may be damaged.

Referring to FIGS. 7 and 8, the protruding portions 415 may be placed on the outer side surface 413S of the brush 413 to be in contact with the outer side surface 413S of the brush 413. Each of the protruding portions 415 may have a second top width TW2 at its top level. Each of the protruding portions 415 may have a second bottom width BW2 at its bottom level. The second top width TW2 may be substantially equal to the second bottom width BW2. The second top width TW2 may be larger than the first top width TW1. In other words, the protruding portions 415 may have a shape of the circular pillar. For example, each of the second top and bottom widths TW2 and BW2 may range from about 8 mm to about 10 mm.

In the edge regions ERB, the protruding portions 415 may have a specific protrusion ratio. For example, the sectional length of the outer side surface 413S of the brush 413 may be given as the product of the first diameter R1 and pi (π), and the sectional length of the top surfaces 415U of the protruding portions 415 may be given as a sum of the second top widths TW2.

In one or more embodiments, the sectional length of the outer side surface 413S of the brush 413 may be the same in the center and edge regions CRB and ERB. Alternatively, the sectional length of the top surfaces 415U of the protruding portions 415 may be different from each other in the center and edge regions CRB and ERB. For example, the second top width TW2 may be larger than the first top width TW1, and the number of the protruding portions 415 may be greater in the edge regions ERB than in the center region CRB. Accordingly, the sectional length of the top surfaces 415U of the protruding portions 415 may be larger in the edge regions ERB than in the center region CRB. Thus, the protrusion ratio in the center region CRB may be smaller than the protrusion ratio in the edge regions ERB.

In one or more embodiments, the protrusion ratio may be greater than about 35% in the edge regions ERB. If the protrusion ratio in the edge regions ERB is less than about 35%, the substrate WF may be weakly cleaned, and it may take a longer time to clean the substrate WF.

Referring to FIG. 9, the horizontal axis of the graph may represent a first distance (where distances measured in the direction DS1 are generally described as first distance) described with reference to FIGS. 2 to 4. For example, first distances of about 0 mm to about 5 mm may correspond to the center portion CRW of the substrate WF and the center region CRB of the brush 413 of FIGS. 2 to 4. First distances of about 140 mm to about 150 mm may correspond to the edge portion ERW of the substrate WF and the edge regions ERB of the brush 413 of FIGS. 2 to 4. The left and right vertical axes of the graph represent a planar area of the substrate and the protrusion ratio, respectively.

A first line G1 may increase linearly as the first distance depicted by the horizontal axis increases. The first line G1 may represent the planar area of the substrate. Referring to FIGS. 2 and 3, the substrate WF may have a circular shape. When viewed in a plan view, the substrate WF may be divided into a plurality of concentric circles according to the first distance, from the center portion CRW to the edge portion ERW. The planar area of each of the concentric circles may increase linearly from the center portion CRW of the substrate WF to the edge portion ERW. That is, the planar area of the substrate WF to be cleaned may increase linearly as the first distance from the center portion CRW of the substrate WF increases.

Similar to the first line G1, a second line G2 may also increase linearly as the first distance depicted by the horizontal axis increases. The second line G2 may represent the protrusion ratio. Referring to FIGS. 5 to 8, the protrusion ratio may be defined as a ratio between the sectional length of the top surfaces 415U of the protruding portions 415 and the sectional length of the outer side surface 413S of the brush 413. Since the brush 413 has a constant sectional length of the outer side surface 413S, the sectional length of the top surfaces 415U of the protruding portions 415 may increase linearly from the center region CRB of the brush 413 to the edge regions ERB. That is, the effective cleaning area of the substrate cleaning brush 410 may be linearly increased from the center region CRB of the brush 413 to the edge regions ERB.

In one or more embodiments, the second line G2 may have a maximum second line G2a and a minimum second line G2b. The second line G2 may be placed between the maximum second line G2a and the minimum second line G2b. Since each of the protruding portions 415 has a circular planar shape, the second line G2 may have the maximum second line G2a and the minimum second line G2b. That is, the second line G2 may have a variation. For example, the second line G2 may have about ±15% variation. In other words, a linear increasing rate of the protrusion ratio of the protruding portions 415 may also have about ±15% variation.

Referring to FIG. 10, the horizontal axis of the graph represents the first distance of FIGS. 2 to 4, as described with reference to FIG. 9. The vertical axis of the graph represents a work per unit area. In the present disclosure, the work per unit area may correspond to the cleaning ability of the substrate cleaning brush 410.

The cleaning ability of the substrate cleaning brush 410 may be affected by a material of the substrate cleaning brush 410, a pressure of the substrate cleaning brush 410, a relative velocity of the substrate cleaning brush 410, and an effective cleaning area, which depends on the planar area of the substrate. In particular, to control a variation of the cleaning ability with respect to one substrate, it may be important to maintain a constant ratio between the planar area of the substrate and the effective cleaning area according to the first distance. The effective cleaning area may be the total area of the top surfaces 415U of the protruding portions 415 described above. That is, the effective cleaning area may be proportional to the protrusion ratio of FIG. 9.

Referring to FIGS. 9 and 10, the planar area of the substrate depicted by the first line G1 may increase linearly as the first distance increases. The protrusion ratio depicted by the second line G2 may also increase linearly as the first distance increases. Accordingly, a ratio between the planar area of the substrate and the effective cleaning area (i.e., the protrusion ratio) may be constant, regardless of the first distance. In other words, the cleaning ability of the substrate cleaning brush 410 may be substantially the same in the center and edge portions CRW and ERW of the substrate WF of FIGS. 2 and 3. Thus, it may be possible to improve the uniformity of the cleaning ability of the substrate cleaning brush 410.

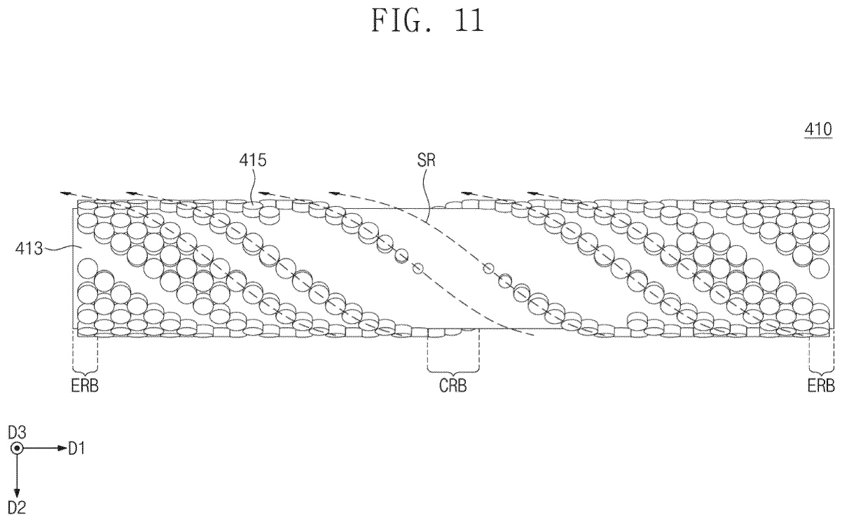

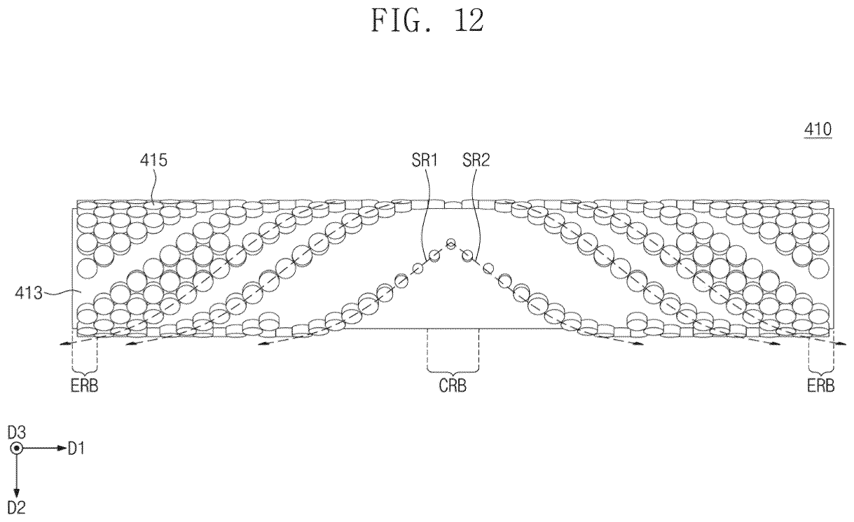

FIGS. 11 and 12 are plan views illustrating a substrate cleaning brush according to one or more embodiments of the present disclosure.

In the following description, an element previously described with reference to FIGS. 4 to 10 may be identified by the same reference number without repeating an overlapping description thereof, for convenience in description.

Referring to FIG. 11, the protruding portions 415 may be placed on the brush 413, between the center region CRB, the edge regions ERB, and the center and edge regions CRB and ERB of the brush 413. The protruding portions 415 may be disposed on the brush 413 in a spiral direction SR. For example, the protruding portions 415 may be disposed on the brush 413 in a spiral configuration or shape. The spiral direction SR may be oblique to the first and second directions D1 and D2.

Due to the protruding portions 415 being disposed in a spiral configuration or shape, the cleaning solution described with reference to FIGS. 2 and 3 may be moved from one of the edge regions ERB to another. For example, the cleaning solution may be moved from one of the edge regions ERB to another in the spiral direction SR. That is, the cleaning solution may be uniformly moved in the first direction D1 or the opposite direction thereof. Accordingly, it may be possible to prevent the substrate cleaning brush 410 and the substrate from being re-contaminated by contaminants, which are removed from the substrate.

Referring to FIG. 12, the protruding portions 415 may be arranged on the brush 413 in a first spiral direction SR1 and a second spiral direction SR2, between the center region CRB, the edge regions ERB, and the center and edge regions CRB and ERB. For example, the protruding portions 415 may be placed on the brush 413 in a symmetrical spiral configuration or shape based on the center region CRB. Each of the first and second spiral directions SR1 and SR2 may be oblique to the first and second directions D1 and D2. The first and second spiral directions SR1 and SR2 may be mirror symmetric directions, when viewed based on the center region CRB.

Due to the protruding portions 415 being arranged in the spiral configuration or shape, the cleaning solution described with reference to FIGS. 2 and 3 may be supplied from the center region CRB to the edge regions ERB. For example, the cleaning solution may be supplied from the center region CRB to one of the edge regions ERB in the first spiral direction SR1 and may be supplied from the center region CRB to the other of the edge regions ERB in the second spiral direction SR2. In one or more embodiments, the cleaning solution may be uniformly supplied in the first direction D1 and the opposite direction thereof, when viewed based on the center region CRB. Accordingly, it may be possible to prevent the substrate cleaning brush 410 and the substrate from being re-contaminated by contaminants, which are removed from the substrate.

Referring back to FIGS. 11 and 12, the protruding portions 415 in the center region CRB may be provided to have a top width less than a bottom width, as described with reference to FIGS. 5 to 8, and the top width of the protruding portion 415 may be larger in the edge regions ERB than in the center region CRB. In addition, as described with reference to FIG. 9, the protruding portions 415 may be disposed to have a linearly increasing protrusion ratio from the center region CRB to the edge regions ERB.

According to one or more embodiments of the present disclosure, a substrate cleaning brush may include a plurality of protruding portions on a brush. At least one of the protruding portions may have a larger width at its lower level than at its upper level. For example, at the center region of the brush, each of the protruding portions may have a bottom width larger than a top width. Accordingly, it may be possible to prevent the protruding portions from being broken. Thus, the durability of the substrate cleaning brush may be improved.

In addition, the protruding portions of the substrate cleaning brush may have a linearly increasing protrusion ratio as it transitions from the center region to the edge regions. Accordingly, the cleaning ability of the substrate cleaning brush may be substantially the same between the center and edge portions of the substrate. Thus, the cleaning ability of the substrate cleaning brush may be uniform.

According to one or more embodiments of the present disclosure, a substrate cleaning brush may include a plurality of protruding portions on a brush. At least one of the protruding portions may have a larger width at its lower level than at its upper level. For example, at the center region of the brush, each of the protruding portions may have a bottom width larger than a top width. Accordingly, it may be possible to prevent the protruding portions from being broken. Thus, the durability of the substrate cleaning brush may be improved.

In addition, the protruding portions of the substrate cleaning brush may have a linearly increasing protrusion ratio as it transitions from the center region to the edge regions. Accordingly, the cleaning ability of the substrate cleaning brush may be substantially the same between the center and edge portions of the substrate. Thus, the cleaning ability of the substrate cleaning brush may be uniform.

While example embodiments of the disclosure have been particularly shown and described, it will be understood by one of ordinary skill in the art that variations in form and detail may be made therein without departing from the spirit and scope of the attached claims.

What is claimed is:

1. A substrate cleaning brush comprising:
a core portion having a cylindrical shape;
a brush on the core portion, the brush comprising a center region and edge regions, wherein the edge regions are on opposite side of the center region; and
a plurality of protruding portions on the brush,
wherein a protrusion ratio of the plurality of protruding portions increases linearly from the center region to the edge regions, and
wherein a width of a bottom level of at least one of the plurality of protruding portions is larger than a width of a top level of the at least one of the plurality of protruding portions.

2. The substrate cleaning brush of claim 1, wherein the protrusion ratio is defined as a ratio between a sectional length of top surfaces of the plurality of protruding portions and a sectional length of an outer side surface of the brush.

3. The substrate cleaning brush of claim 1, wherein a top width of each of the plurality of protruding portions in the center region is smaller than a top width of each of the plurality of protruding portions in the edge regions.

4. The substrate cleaning brush of claim 1, wherein the protrusion ratio in the center region is less than 5%.

5. The substrate cleaning brush of claim 1, wherein the plurality of protruding portions are symmetrically arranged about the center region.

6. The substrate cleaning brush of claim 1, wherein the protrusion ratio is greater than 35% in the edge regions.

7. The substrate cleaning brush of claim 1, wherein a rate of the linear increase of the protrusion ratio has a ±15% variation.

8. The substrate cleaning brush of claim 1, wherein the plurality of protruding portions are spaced apart from each other and expose a portion of an outer side surface of the brush.

9. The substrate cleaning brush of claim 1, wherein the plurality of protruding portions are in a spiral configuration on the brush.

10. The substrate cleaning brush of claim 9, wherein the plurality of protruding portions are mirror-symmetric about the center region.

11. A substrate cleaning brush comprising:
a core portion having a cylindrical shape;
a brush on the core portion, the brush comprising a center region and edge regions, wherein the edge regions are on opposite sides of the center region; and
a plurality of protruding portions on the brush,
wherein at least a portion of the plurality of protruding portions are on the brush in a spiral configuration, and
wherein a width of a bottom level of at least one of the plurality of protruding portions is larger than a width of a top level of the at least one of the plurality of protruding portions.

12. The substrate cleaning brush of claim 11, wherein a top width of the plurality of protruding portions is larger with regard to protruding portions in the edge regions among the plurality of protruding portions as compared to protruding portions in the center region among the plurality of protruding portions.

13. The substrate cleaning brush of claim 11, wherein a number of the plurality of protruding portions in the edge regions is greater than a number of the plurality of protruding portions in the center region.

14. The substrate cleaning brush of claim 11, wherein the brush comprises poly vinyl alcohol (PVA) and has a porous structure.

15. The substrate cleaning brush of claim 11, wherein the plurality of protruding portions are symmetrically arranged about the center region.

16. The substrate cleaning brush of claim 11,
wherein a protrusion ratio of the plurality of protruding portions is a ratio between a sectional length of top surfaces of the plurality of protruding portions and a sectional length of an outer side surface of the brush, and
wherein the protrusion ratio increases linearly from the center region to the edge regions.

17. A substrate processing apparatus comprising:
a polisher configured to polish a surface of a substrate using a polishing pad; and
a cleaner configured to clean and dry the substrate,
wherein the cleaner comprises:
a brush comprising a center region and edge regions; and
a plurality of protruding portions protruding from the brush, and
wherein a protrusion ratio of the plurality of protruding portions increases linearly from the center region to the edge regions.

18. The substrate processing apparatus of claim 17, wherein a top width of the plurality of protruding portions increase from the center region to the edge regions.

19. The substrate processing apparatus of claim 17, wherein the plurality of protruding portions are arranged in a spiral shape on the brush.

20. The substrate processing apparatus of claim 17, wherein a width of a bottom level of at least one of the plurality of protruding portions is larger than a width of a top level of the at least one of the plurality of protruding portions.
